(19) United States
(12) Patent Application Publication
(10) Pub. No.: US 2026/0261094 A1
(43) Pub. Date: Sep. 3, 2026

(54) INTEGRATED PHOTONIC TRANSMISSION CIRCUIT CAPABLE OF OPERATING OVER AN EXTENDED TEMPERATURE RANGE

(71) Applicant: Scintil Photonics, Grenoble (FR)

(72) Inventor: Sylvie Menezo, Grenoble (FR)

(21) Appl. No.: 19/163,551

(22) PCT Filed: Feb. 26, 2024
(86) PCT No.: PCT/EP2024/054776

§ 371 Date: Sep. 9, 2025

(30) Foreign Application Priority Data
Mar. 14, 2023 (FR) FR2302328

(51) Int. Cl. H01S 5/026

(52) U.S. Cl. CPC H01S 5/026

(57) ABSTRACT

An integrated photonic transmission circuit includes a laser source for producing light radiation and comprising a grating defining a transmission wavelength and a first amplifying medium having a first photoluminescence wavelength and a semiconductor optical amplifier comprising a second amplifying medium having a second photoluminescence wavelength. The laser source and the optical amplifier are configured such that, at a first temperature the transmission wavelength is closer to the first photoluminescence wavelength than to the second and, at a second temperature, the transmission wavelength is closer to the second photoluminescence wavelength than to the first.

### CROSS-REFERENCE TO RELATED APPLICATIONS

This application is a national phase entry under 35 U.S.C. § 371 of International Patent Application PCT/EP2024/054776, filed Feb. 26, 2024, designating the United States of America and published as International Patent Publication WO 2024/188623 A1 on Sep. 19, 2024, which claims the benefit under Article 8 of the Patent Cooperation Treaty of French Patent Application Serial No. FR2302328, filed Mar. 14, 2023.

### TECHNICAL FIELD

The present disclosure relates to an integrated photonic transmission circuit. Such a circuit can be used in the field of telecommunications to create a transmission component, or in the field of sensors, for example, to create a LIDAR component.

### BACKGROUND

Integrated photonic circuits are integrated circuits capable of generating, detecting or manipulating light radiation. These circuits, like electronic integrated circuits, can incorporate multiple functional blocks on a single substrate (e.g., a silicon-based substrate), such as laser sources, switches, modulators, amplifiers and power distributors, these blocks being interconnected by waveguides.

An integrated photonic transmission circuit is equipped with a source of light radiation, typically a laser source. In a manner well known per se (see, for example, EP2811593), such a source comprises an optical amplifying medium formed by a stack of layers of III-V materials constituting at least one hetero junction or so-called “active” region, for example, a plurality of quantum wells. This stack can be made from materials selected from the following non-exhaustive list: InP, AsGa, InGaAlAs, InGaAsP, InAsP. The choice of materials for this stack defines the photoluminescence wavelength of the amplifying medium. The amplifying medium is characterized by its amplification gain, which is a function of wavelength. This function peaks at the “photoluminescence” wavelength, and decreases on both sides of this wavelength to define an amplification bandwidth typically on the order of 30 nm.

The amplifying medium is arranged, for example, as a ribbon, in line with a portion of a waveguide, known as the coupling portion, the waveguide being made, for example, of silicon. Circulating a current through this medium pumps it electrically to establish a hybrid optical mode in both the amplifying medium and the waveguide portion. The laser effect is achieved by means of a feedback structure that forms a resonant cavity. This structure can be produced by a distributed reflector, for example, a Bragg grating, arranged in the amplifying medium or in the wave guide. The Bragg grating defines the transmission wavelength of the light radiation produced by the laser source. The hybrid optical mode formed in the amplifying medium and in the coupling portion of the underlying waveguide tends to propagate in the waveguide.

EP3538937 proposes to form such a laser source (as well as the other active elements of the integrated photonic circuit) by “die bonding,” that is, by transferring a section of III-V materials onto the coupling portion of a waveguide using a layer transfer technique. In other approaches, the section of layers of III-V materials forming the amplifying medium is deposited, for example, by epitaxial deposition, on the coupling portion of the waveguide. This section of materials is processed, in particular, by etching, to form the electrical contacts on both sides of the junction to form a functional laser diode. When the aim is to produce a plurality of active elements, for example, a plurality of laser sources, the section of III-V materials can also be structured to individualize a plurality of diodes arranged in line with a plurality of waveguide coupling portions. This approach, the details and variants of which can be found in the above-mentioned document EP3538937, is highly advantageous in that it simplifies the manufacture of integrated photonic transmission circuits. This is particularly the case when these include several active elements with amplifying mediums made of the same materials, by allowing the collective manufacture of these active elements.

To produce light radiation with satisfactory power, the transmission wavelength of the light radiation (defined by the period of the Bragg grating) and the photoluminescence wavelength of the amplifying medium (defined by the nature of the materials defining the stack) are chosen to match one another. As a minimum, an effort is made to place the transmission wavelength of the light beam within the amplification bandwidth of the amplifying medium.

However, as recalled by US2011/0211603, these wavelengths drift with the operating temperature of the laser source. Thus, the transmission wavelength of the light radiation, referred to as L_{bragg} in the following description, tends to increase with temperature, this increase being on the order of 0.1 nm/° C. The gain function and gain peak of the amplifying medium, however, tend to increase much more significantly with temperature, on the order of 0.6 nm/° C.

FIG. 1 shows the evolution of the gain L₁ of the amplifying medium and the transmission wavelength L_{bragg} of a laser source of the state of the art, in the decibel (dB)/wavelength (nm) reference frame. It shows the phenomena occurring at three increasing temperatures T0, T1, T2 as a result of these differentiated drifts. First, it will be noted that the gain function of the amplifying medium G(T0), G(T1), G(T2), and, in particular, the amplitude of the gain peak, tends to decrease with temperature.

At a relatively low operating temperature T0, the transmission wavelength L_{bragg}(T0) is located in the gain bandwidth of the amplifying medium, at a wavelength greater than the wavelength L₁(T0) of the gain peak. Although at this transmission wavelength L_{bragg}(T0) the gain is not maximum, this situation is not unfavorable, since at relatively low temperature T0 the gain remains relatively high. The transmission power of the radiation can therefore be satisfactory.

At an intermediate operating temperature T1, due to the drifts induced by the rise in temperature on the gain function and on the transmission wavelength, the transmission wavelength L_{bragg}(T1) is arranged at a wavelength close to the wavelength L₁(T1) of the gain peak. This situation is favorable because the amplification provided is at or near its maximum.

At a relatively high operating temperature T2, the transmission wavelength L_{bragg}(T2) is this time arranged in the lower bandwidth portion of the gain of the amplifying medium, at a wavelength shorter than the wavelength L₁(T2) of the gain peak. This situation is not favorable, as it combines a gain function weakened by the relatively high operating temperature, with the transmission wavelength L_{bragg}(T2) in a portion far from the peak of this function. The power of the light emitted is therefore particularly low.

It is therefore understood that the laser source is able to produce light radiation with satisfactory power, above a desired power threshold, within a limited operating temperature range, in the [T0, T1] range in the example of FIG. 1.

To increase the power of the light radiation produced by the source, a semiconductor optical amplifier (SOA) can be added to the laser source, integrated into the integrated photonic circuit. An example of such an integrated circuit is, in particular, described in document US2013/0107900. This amplifier is arranged end-to-end (that is, without an intermediate waveguide) with the laser source and, like the laser source, has an amplifying medium prepared from the same materials as the source. Although the semiconductor optical amplifier can extend the temperature range for satisfactory laser source operation, by increasing the overall gain function applied to the light radiation produced, the integrated photonic circuit is still subject to the same temperature drift effects and therefore has the same limitations as those presented with reference to FIG. 1.

In US2003/0210723, the laser source and optical amplifier are monolithically integrated, that is, they share the same active region.

It is therefore still desirable to extend the operating temperature range of integrated photonic transmission circuits.

### BRIEF SUMMARY

One aim of the present disclosure is to provide at least a partial solution to this problem. More particularly, one aim of the present disclosure is to provide an integrated photonic transmission circuit with a wider operating temperature range than those of prior art integrated circuits.

With a view to achieving this aim, the object of the present disclosure proposes an integrated photonic transmission circuit that includes a laser source for producing light radiation, a semiconductor optical amplifier, and at least one passive waveguide arranged between the laser source and the semiconductor optical amplifier to transmit the light radiation produced by the laser source to the semiconductor optical amplifier. The laser source includes a grating defining a transmission wavelength and a first amplifying medium having a first photoluminescence wavelength. The semiconductor optical amplifier includes a second amplifying medium electrically isolated from the first amplifying medium and separated by a separation distance from the first amplifying medium. The semiconductor optical amplifier has a second photo luminescence wavelength. The laser source and the semiconductor optical amplifier are configured so that: i. at a first temperature of 20° C., the transmission wavelength is closer to the first photoluminescence wavelength than to the second photo luminescence wavelength, and ii. at a second temperature of 80° C., the transmission wavelength is closer to the second photoluminescence wavelength than to the first photoluminescence wavelength.

According to other advantageous and non-limiting features of the present disclosure, either individually or in any technically feasible combination:
the first amplifying medium of the laser source and the second amplifying medium of the amplifier are configured so that their respective photoluminescence wavelengths at the first temperature are separated by a wavelength spacing less than or equal to their temperature drifts at the second temperature;
the first amplifying medium is selected so that, over a temperature range between the first temperature and the second temperature, the difference between the transmission wavelength and the first photoluminescence wavelength is less than half the bandwidth of the first amplifying medium;
the integrated photonic transmission circuit comprises a plurality of laser sources having a first amplifying medium of identical composition, a plurality of semiconductor optical amplifiers having a second amplifying medium of identical composition, and a plurality of waveguides respectively disposed between the laser sources and the semiconductor optical amplifiers for respectively transmitting the light radiation produced by the laser sources to the semiconductor optical amplifiers;
the integrated photonic transmission circuit comprises a plurality of complementary semiconductor optical amplifiers having a second complementary amplifying medium of identical composition and having a complementary photoluminescence wavelength less than or equal to the second photoluminescence wavelength at the first temperature;
the integrated photonic transmission circuit comprises, optically downstream of the plurality of semiconductor optical amplifiers and the plurality of complementary semiconductor optical amplifiers, a plurality of optical switches, each optical switch being connected to a semiconductor optical amplifier and to a complementary semiconductor optical amplifier;
the integrated photonic transmission circuit comprises a plurality of laser sources and a plurality of semiconductor optical amplifiers, the laser sources and semiconductor optical amplifiers having, in pairs, an amplifying medium of the same composition, and a plurality of waveguides respectively disposed between laser sources and semiconductor optical amplifiers having amplifying mediums of different compositions;
the integrated photonic transmission circuit further comprises a wavelength multiplexer arranged downstream of the plurality of semiconductor optical amplifiers and optically connected to the semiconductor optical amplifiers to produce multispectral light radiation;
the integrated photonic transmission circuit comprises at least one additional optical device arranged between the laser source and the semiconductor optical amplifier;
the additional optical device is a modulator or a switch.

### BRIEF DESCRIPTION OF THE DRAWINGS

Other features and advantages of the present disclosure will become apparent from the following detailed description of example embodiments of the present disclosure with reference to the appended figures, in which:

FIG. 1 shows the phenomenon of thermal drift applied to an integrated photonic transmission circuit and its impact on the power of the light radiation produced by this circuit;

FIGS. 2A and 2B show, in top view, the schematic diagram of an integrated photonic transmission circuit 1 according to embodiments;

FIG. 3 shows, in a power/wavelength reference frame, the evolution of the gains of the amplifying mediums A1, A2 and of the transmission wavelength L_{bragg} of the photonic circuit 1 configured according to the present disclosure, with the operating temperature of the circuit;

FIG. 4 shows an integrated photonic transmission circuit in a parallel configuration;

FIG. 5 shows an example of another embodiment of an integrated photonic circuit in a parallel configuration;

FIG. 6 shows the operation of the photonic circuit shown in FIG. 5; and

FIG. 7 shows an example of another embodiment of a photonic circuit conforming to the present disclosure, in a series configuration.

### DETAILED DESCRIPTION

FIG. 2A shows a schematic diagram of an integrated photonic transmission circuit 1 in a top view. This photonic circuit 1 comprises, monolithically integrated on a substrate, a laser source LS, a semiconductor optical amplifier SOA (more simply referred to as “amplifier” in the remainder of this disclosure), and a waveguide WG arranged between the laser source LS and the amplifier SOA.

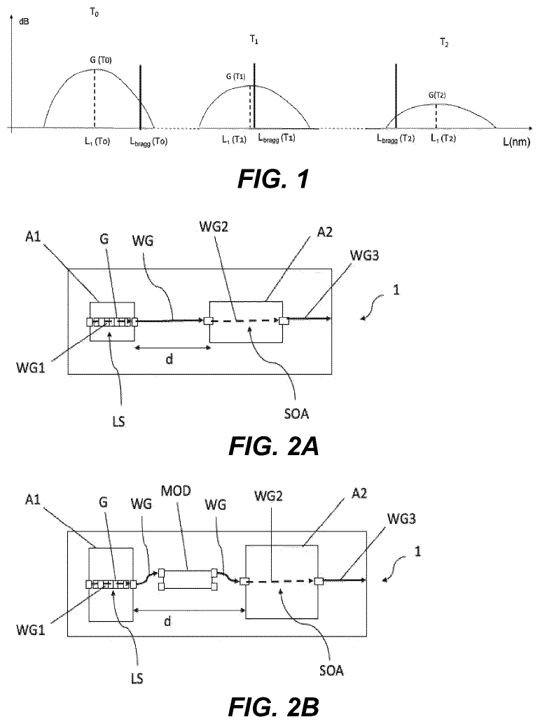

The laser source LS comprises a first amplifying medium A1. As already mentioned in the introduction to this disclosure, this medium is formed by a stack of layers of III-V materials constituting at least one hetero junction, for example, based on InP, AsGa, InGaAlAs, InGaAsP or InAsP. The first amplifying medium A1 here takes the general form of a ribbon arranged in line with a first coupling portion of a waveguide WG1, for example, made of silicon, in which an optical mode is established when a first current flows through the first amplifying medium A1. For the sake of simplicity, the schematic diagram in FIG. 1 does not show the circuits, tracks and contacts used to inject this current.

The first amplifying medium A1 has a first photoluminescence wavelength L₁, which depends on the composition of an active region of this medium and its operating temperature. The active region may correspond to quantum wells based on III-V quaternary compounds (InGaAlAs, InGaAsP) or quantum dots based on InGaAs. The active region is sandwiched between a layer of N-type semiconductor material and a layer of P-type semiconductor material. These layers, typically based on InP or AsGa, enable a current to flow through the active region, and electrically pump the amplifying medium to enable light generation.

The laser source also comprises a grating G made in the first amplifying medium A1 or in the first waveguide portion WG1, for example, a Bragg grating. The grating G defines, in particular, through its pitch, a transmission wavelength L_{bragg} of the laser source LS.

Continuing the description of the schematic diagram in FIG. 2A, the amplifier SOA comprises a second amplifying medium A2 with a second photoluminescence wavelength L_{gain}. This second amplifying medium A2 is different from the first amplifying medium A1, that is, it is composed of a stack of III-V materials with different compositions from the III-V materials making up the first amplifying medium A1. As a result, the second photoluminescence wavelength L_{gain} is different from the first photoluminescence wavelength L₁.

The second amplifying medium A2 also takes the general form of a section arranged in line with a second waveguide portion WG2, extending between an input and an output of the amplifier, and in which the optical mode generated by the laser source LS propagates and is amplified when this second medium A1 is traversed by a second current. For the sake of simplicity, the schematic diagram in FIG. 2A does not show the circuits, tracks and contacts used to inject this current.

In any case, the first current flowing in the first amplifying medium A1 and the second current flowing in the second amplifying medium A2 are distinct from one another, these two mediums being electrically isolated. Each of these mediums A1, A2 is provided with contacts, tracks and circuits to control these currents, and the operation of the laser source and amplifier SOA independently of one another.

It should be noted that independent control of the gain of the laser source and the gain of the amplifier SOA, by injecting different currents therein, is a notable advantage of a photonic circuit conforming to the present disclosure, in that it offers the ability to adapt these gains according to temperature.

The passive waveguide WG is arranged between the laser source LS and the input of the amplifier SOA, to transmit the light radiation produced by the source LS to the amplifier SOA. It connects the first waveguide portion WG1 and the second waveguide portion WG2, which are therefore not arranged end-to-end as is the case in the photonic circuits of the prior art reported in the introduction to this disclosure.

Note that the amplifying mediums A1, A2 of the laser source LS and the amplifier SOA are distinct from one another, electrically isolated from each other, and made of materials of different compositions, so they cannot be contiguous or consist of a single monolithic block of material. They are therefore separated by a separation distance d, requiring the presence of the waveguide WG to propagate the optical mode from the laser source LS to the amplifier SOA.

Of course, the integrated photonic transmission circuit 1 may feature other elements that can be optically inserted, for example, between the laser source LS and the amplifier SOA, via a plurality of waveguides WG. FIG. 2B shows a photonic circuit 1 of another type, comprising a modulator MOD, optically connected by waveguides WG to the laser source LS and the amplifier SOA. FIGS. 2A and 2B also show an output waveguide WG3, optically connecting the amplifier output to, for example, a component for coupling the optical flow from the photonic circuit 1 to an optical fiber. Other coupling configurations of the photonic circuit 1 are alternatively possible, for example, via a surface grating coupled to the output waveguide WG3.

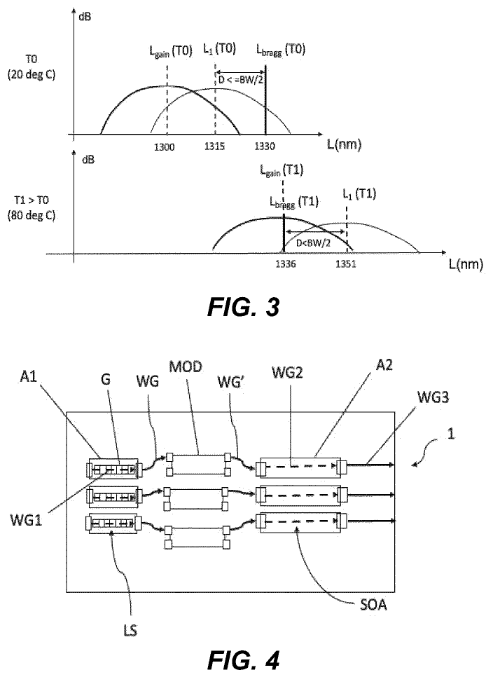

FIG. 3 shows, in a power/wavelength reference frame, the evolution of the gains of the amplifying mediums A1, A2 and of the transmission wavelength L_{bragg} of the photonic circuit 1 configured according to the present disclosure, with the operating temperature of the circuit.

At a first relatively low operating temperature T0, which may correspond to room temperature (20° C.), the transmission wavelength L_{bragg}(T0) is located in the gain bandwidth of the first amplifying medium A1, at a wavelength greater than the wavelength L₁(T0) of the gain peak. This configuration is obtained by choosing the nature of the first amplifying medium A1 and defining the parameters of the grating of the laser source LS.

By way of example, at a first temperature corresponding to room temperature (20° C.), the transmission length L_{bragg} is 1330 nm, and the photoluminescence wavelength L₁ of the first amplifying medium A1 (the gain peak of this first medium) is chosen to correspond to 1315 nm.

The gain bandwidth of the second amplifying medium A2 (thick line in FIG. 3) is configured, by choosing the nature of the materials making up this medium, to be offset from the gain bandwidth of the first amplifying medium A1 toward shorter wavelengths. However, it is advantageous to ensure that the amplifier SOA is “transparent,” that is, that its gain at the transmission wavelength L_{bragg} of the laser source LS is not less than 0 dB, at the first temperature T0.

By way of example, the photoluminescence wavelength L_{gain} of the second amplifying medium A2 (the gain peak of this second medium) is chosen to correspond to 1300 nm, that is, 15 nm lower than the photoluminescence wavelength of the first medium L₁.

In this configuration at the first temperature T0, and as is clearly visible in FIG. 3, the transmission wavelength L_{bragg} is closer to the first photoluminescence wavelength L₁ than to the second photoluminescence wavelength L_{gain}.

The amplifier SOA contributes little to the amplification of the optical mode produced by the laser source LS. The optical mode produced by the laser source LS alone has sufficient power, above a specified threshold, and requires little or no additional amplification.

As the operating temperature of the photonic circuit rises, the transmission wavelength L_{bragg} and the first and second photoluminescence wavelengths L₁, L_{gain} drift according to different dynamics.

Thus, at a second, relatively high operating temperature T1, which may be 80° C. or 100° C., the first and second photoluminescence wavelengths L₁, L_{gain} are shifted toward the longer wavelengths by a difference on the order of 0.6 nm per ° C. of temperature rise (that is, the difference T1-T0). The gain functions of the first and second amplifying mediums A1, A2 are also smaller at the second temperature T1 than at the first T0. The transmission wavelength L_{bragg} is shifted toward the longer wavelengths by about 0.1 nm per ° C. of temperature rise (T1-T0).

Continuing with the example described above, and taking the second temperature T2 at 80° C., 60° higher than the first temperature T0 chosen at room temperature, the transmission wavelength L_{bragg} (T1) is shifted by 6 nm to 1336 nm, and the first and second photoluminescence wavelengths L₁, L_{gain} are shifted by 36 nm to 1351 nm and 1336 nm, respectively.

As a result, and due to this differentiated temperature drift dynamic, the transmission wavelength L_{bragg}(T1) is arranged, at the second operating temperature T1, in the gain bandwidth of the first amplifying medium A1, at a wavelength shorter than the wavelength L₁(T1) of the gain peak. This transmission wavelength L_{bragg}(T1) is also located within the gain bandwidth of the second amplifying medium A2.

At the second temperature T1, the transmission wavelength L_{bragg} is closer to the second photoluminescence wavelength L_{gain} than to the first photoluminescence wavelength L₁.

As a result, the amplifier SOA contributes to the amplification of the optical mode produced by the laser source LS. This amplification at least compensates for the lower gains of the amplifying mediums A1, A2 at the relatively higher temperature T1, in order to maintain an optical mode of sufficient power, above the determined threshold.

By differentiating the two amplifying mediums A1, A2 of the laser source LS and the amplifier SOA and configuring them so that their photoluminescence wavelength L₁, L_{gain} is shifted by a wavelength deviation less than or equal to their temperature drift over a target temperature range [T0-T1], it is ensured that the optical mode produced by the laser source LS is sufficiently amplified by the first amplification medium A1 of the laser source LS and/or by the second amplification medium A2 of the amplifier SOA to keep its power above the determined threshold over the extended target temperature range.

Advantageously, the first amplifying medium A1 is selected so that, over a temperature range between the first temperature T0 and the second temperature T1, the deviation D between the transmission wavelength L_{bragg} and the first photoluminescence wavelength L₁ is less than half a bandwidth BW/2 of the first amplifying medium A1. This ensures that over the entire temperature range [T0-T1], the laser source produces an optical mode whose power is greater than a minimum power. The bandwidth BW of the first amplifying medium A1 can be set at 3 dB, for example, as is customary.

The first temperature T0 can be ambient temperature and the second temperature can be 60° C., 80° C. or 100° C., depending on the operating range targeted by the photonic circuit 1.

The above principles of the present disclosure can be deployed in many different ways.

Thus, FIG. 4 shows an integrated photonic transmission circuit 1 in a parallel configuration. This circuit comprises a plurality of identical laser sources LS. These laser sources LS each comprise a grating defining the same transmission wavelength L_{bragg}. They also each comprise a first amplifying medium A1, these amplifying mediums A1 all being of the same composition and therefore defining the same first photoluminescence wavelength L₁. Advantageously, this medium is derived from a single monolithic section of III-V materials formed in line with a plurality of first waveguide portions WG1, and structured to define the plurality of laser sources LS therein, as set out in the introduction to this disclosure.

The photonic circuit 1 also comprises a plurality of semiconductor optical amplifiers SOA, each comprising a second amplifying medium A2 having the same composition and thus defining the same second photoluminescence wavelength L_{gain}. Advantageously, and as explained in the case of the first amplifying medium A1, this second medium A2 is derived from a single monolithic section of III-V materials shaped and structured in line with a plurality of second waveguide portions WG2.

Finally, the photonic circuit 1 comprises a plurality of waveguides WG, WG′ arranged between the laser sources LS and the semiconductor optical amplifiers SOA for respectively transmitting the light radiation produced by the laser sources LS to the semiconductor optical amplifiers SOA. In the embodiment shown in FIG. 4, modulators MOD are also provided between a laser source LS and an amplifier SOA, respectively, to form an integrated photonic transmission circuit, but this element is completely optional or could be replaced by an optical element providing another function.

The nature of the amplifying mediums A1, A2 and the transmission wavelength L_{bragg} are chosen in accordance with what was presented during the description of the previous figures: very generally, at the first temperature T0, the transmission wavelength L_{bragg} is closer to the first photoluminescence wavelength L₁ than to the second photoluminescence wavelength L_{gain}. At the second temperature T1, which is higher than the first temperature T0, the transmission wavelength L_{bragg} is closer to the second photoluminescence wavelength L_{gain} than to the first photoluminescence wavelength L₁.

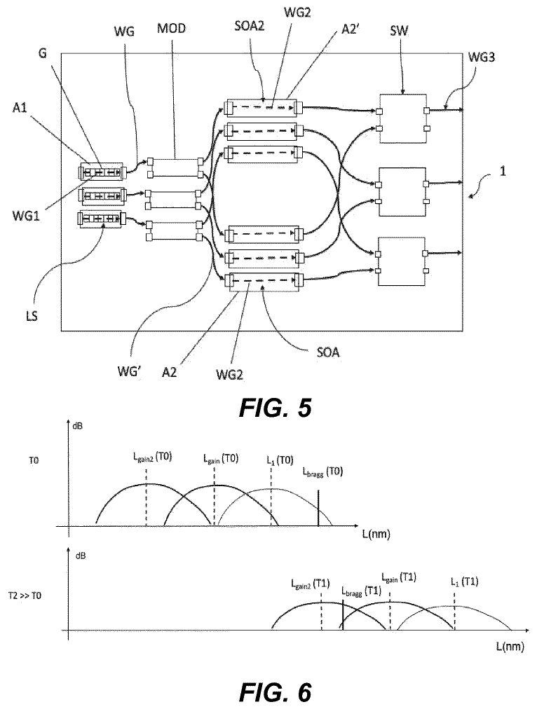

FIG. 5 shows another embodiment of a photonic circuit 1 in a parallel configuration.

The photonic circuit of FIG. 5 features a plurality of laser sources LS and modulators MOD in the same configuration as in FIG. 4. Each laser source LS is optically connected to an input of a modulator MOD via a waveguide WG. Output channels of the modulators MOD are respectively connected via further waveguides WG′ to semiconductor optical amplifiers SOA featuring the same second amplifying medium A2. These elements are configured in the same way as the configuration of the embodiment of FIG. 4.

Advantageously, the modulators MOD each have two outputs in phase opposition. This may be a Mach Zender-type silicon modulator. Alternatively, the modulators could be replaced by simple switches, also featuring two outputs to which the energy of the light radiation propagating from their inputs is distributed.

In the case of the integrated circuit shown in FIG. 5, the second output (not connected to the semiconductor optical amplifier SOA) is optically connected, via the waveguides WG', to a plurality of complementary semiconductor optical amplifiers SOA2. These complementary amplifiers SOA2 feature the same complementary amplifying medium A2′, which differs from the second amplifying medium A2. More specifically, the complementary amplifying medium A2′ has a complementary photoluminescence wavelength L_{gain2} less than or equal to the second photoluminescence wavelength L_{gain} at the first temperature T0.

As shown in FIG. 6, such a photonic circuit configuration extends the operating temperature range of the photonic circuit, with the complementary amplifiers SOA2 amplifying the optical modes when the temperature drift no longer allows the amplifiers SOA to provide sufficient gain.

Downstream of the amplifiers SOA and the complementary amplifiers SOA2, a plurality of optical switches SW are provided for selecting, from the plurality of outputs of the amplifiers SOA and the complementary amplifiers SOA2, and depending on the effective operating temperature of the circuit 1, the amplified radiation that is propagated by the output waveguides WG3 to the transmission output of the integrated photonic circuit 1.

More specifically, at a relatively low temperature, the switches are operated to propagate radiation from the amplifiers SOA toward the output waveguides WG3. At a relatively high temperature, the switches are operated to propagate radiation from the complementary amplifiers SOA2 through the output waveguides WG3.

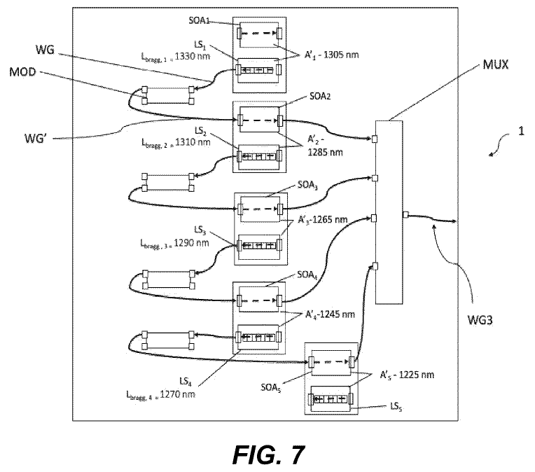

FIG. 7 shows still another example of an embodiment of a photonic circuit 1 conforming to the present disclosure, this time in a so-called wavelength-division multiplex configuration.

In this configuration, a plurality of laser sources LS₁-LS₅ and a plurality of semiconductor optical amplifiers SOA₁-SOA₅ comprise, in pairs, an identically constituted amplifying medium A′₁-A′₅. In other words, a single-composition amplifying medium Aᵢ is placed in line with a first waveguide portion of a laser source LSᵢ and in line with a second waveguide portion of an amplifier SOAᵢ. A plurality of waveguides WG, WG′ are respectively arranged between laser sources LSᵢ and optical amplifiers SOAᵢ₊₁, the first amplifying medium Aᵢ of the laser source LSᵢ being of different composition from the second amplifying medium Aᵢ₊₁ of the optical amplifier SOAᵢ₊₁, for respectively transmitting the light radiation produced by the laser sources LSᵢ to the semiconductor optical amplifiers SOAᵢ₊₁.

In the example shown, the photonic circuit comprises five types of amplifying mediums A′₁-A′₅, each derived from a section of III-V material formed and structured in line with a first waveguide portion of a laser source LS and a second waveguide portion of an amplifier SOA. The laser source LSᵢ is also equipped with a grating defining a transmission wavelength L_{bragg.i}. The nature of the amplifying medium A′ᵢ and the transmission wavelength L_{bragg.i} are therefore chosen to enable the laser source LSᵢ and the amplifier SOAI to operate correctly.

The circuit shown features a plurality of laser sources LSᵢ, each with a different transmission wavelength L_{bragg.i} and a plurality of amplifiers SOAᵢ. The transmission wavelengths L_{bragg.1}-L_{bragg.5} are staggered (1330 nm, 1310 nm, 1290 nm, 1245 nm, 1270 nm and 1225 nm as shown in FIG. 7) to provide a plurality of light radiations that can be combined or wavelength-multiplexed with one another and form multi-wavelength radiation at the output of the photonic circuit 1. The materials of the amplifying mediums A′₁-A′₅ are selected to evenly stagger their photoluminescence wavelengths (1305 nm, 1285 nm, 1265 nm, 1245 nm and 1225 nm).

As shown in FIG. 7, waveguides WG are used to optically couple a laser source LS comprising a first amplifying medium A′ᵢ having a first photoluminescence wavelength to an amplifier SOA comprising a second amplifying medium A′ᵢ₊₁ having a second photoluminescence wavelength.

This chaining via waveguides WG, WG′ is repeated to couple a laser source LSᵢ associated with a first amplifying medium Aᵢ to an amplifier SOAᵢ₊₁ associated with a second amplifying medium Aᵢ₊₁, different from the first.

Note that in the chain shown in FIG. 7, the first amplifier of the chain SOA₁, associated with the amplifying medium designated A′₁ in FIG. 7, and the last laser source LS₅, associated with the amplifying medium designated A′₅ in FIG. 7, are not used. As these two elements are not exploited, they can be omitted.

This wavelength-multiplexed embodiment has the advantage of limiting the number of amplifying mediums of different composition (sections) used to manufacture the optical device, by pooling their use. The structure shown in FIG. 7, for example, requires five sections of different types, the sections being structured to create the first and second amplifying mediums associated with the 4 laser sources LSᵢ and the 4 amplifiers SOAᵢ, that is, 8 amplifying mediums.

Naturally, the present disclosure is not limited to the embodiments described, and it is possible to add alternative embodiments without departing from the scope of the invention as defined by the claims.

1. An integrated photonic transmission circuit circuit, comprising:
a laser source for producing light radiation and comprising a grating defining a transmission wavelength and a first amplifying medium having a first photoluminescence wavelength;
a semiconductor optical amplifier comprising a second amplifying medium, electrically isolated from the first amplifying medium and separated by a separation distance from the first amplifying medium, the semiconductor optical amplifier having a second photoluminescence wavelength; and
at least one passive waveguide arranged between the laser source and the semiconductor optical amplifier to transmit the light radiation produced by the laser source to the semiconductor optical amplifier; and
wherein the laser source and the semiconductor optical amplifier are configured so that:
i. at a first temperature of 20° C., the transmission wavelength is closer to the first photoluminescence wavelength than to the second photoluminescence wavelength, and
ii. at a second temperature of 80° C., the transmission wavelength is closer to the second photoluminescence wavelength than to the first photoluminescence wavelength.

2. The integrated photonic transmission circuit toof claim 1, wherein the amplifying mediums of the laser source and the amplifying mediums of the amplifier are configured so that their respective photoluminescence wavelengths at the first temperature of 20° C. are separated by a wavelength spacing less than or equal to their temperature drifts at the second temperature

3. The integrated photonic transmission circuit of claim 2, wherein the first amplifying medium is selected configured so that, over a temperature range between the first temperature of 20° C. and the second temperature of 80° C., the deviation between the transmission wavelength and the first photoluminescence wavelength is less than half a bandwidth of the first amplifying medium.

4. The integrated photonic transmission circuit of claim 3, further comprising a plurality of laser sources having a first amplifying medium of identical composition, a plurality of semiconductor optical amplifiers having a second amplifying medium of identical composition, and a plurality of waveguides respectively disposed between the laser sources and the semiconductor optical amplifiers for respectively transmitting the light radiation produced by the laser sources to the semiconductor optical amplifiers

5. The integrated photonic transmission circuit of claim 4, further comprising a plurality of complementary semiconductor optical amplifiers having a second complementary amplifying medium of identical composition and having a complementary photoluminescence wavelength less than or equal to the second photoluminescence wavelength at the first temperature of 20° C.

6. The integrated photonic transmission circuit of claim 5, further comprising, optically downstream of the plurality of semiconductor optical amplifiers and the plurality of complementary semiconductor optical amplifiers a plurality of optical switches each optical switch being connected to a semiconductor optical amplifier and to a complementary semiconductor optical amplifier.

7. The integrated photonic transmission circuit of claim 3, further comprising a plurality of laser sources and a plurality of semiconductor optical amplifiers the laser sources and semiconductor optical amplifiers having, in pairs, an amplifying medium of the same composition, and a plurality of waveguides respectively disposed between laser sources and semiconductor optical amplifiers having amplifying mediums of different compositions.

8. The integrated photonic transmission circuit of claim 7, further comprising a wavelength multiplexer arranged downstream of the plurality of semiconductor optical amplifiers and optically connected to the semiconductor optical amplifiers to produce multispectral light radiation.

9. The integrated photonic transmission circuit of claim 8, further comprising at least one additional optical device arranged between the laser source and the semiconductor optical amplifier.

10. The integrated photonic transmitter circuit of claim 9, wherein the additional optical device is a modulator or a switch.

11. The integrated photonic transmission circuit of claim 1, wherein the first amplifying medium is configured so that, over a temperature range between the first temperature of 20° C. and the second temperature of 80° C., the deviation between the transmission wavelength and the first photoluminescence wavelength is less than half a bandwidth of the first amplifying medium.

12. The integrated photonic transmission circuit of claim 1, further comprising a plurality of laser sources having a first amplifying medium of identical composition, a plurality of semiconductor optical amplifiers having a second amplifying medium of identical composition, and a plurality of waveguides respectively disposed between the laser sources and the semiconductor optical amplifiers for respectively transmitting the light radiation produced by the laser sources to the semiconductor optical amplifiers.

13. The integrated photonic transmission circuit toof claim 12, further comprising a plurality of complementary semiconductor optical amplifiers having a second complementary amplifying medium of identical composition and having a complementary photoluminescence wavelength less than or equal to the second photoluminescence wavelength at the first temperature of 20° C.

14. The integrated photonic transmission circuit of claim 13, further comprising, optically downstream of the plurality of semiconductor optical amplifiers and the plurality of complementary semiconductor optical amplifiers a plurality of optical switches-(SW), each optical switch being connected to a semiconductor optical amplifier and to a complementary semiconductor optical amplifier.

15. The integrated photonic transmission circuit of claim 1, further comprising a plurality of laser sources-and a plurality of semiconductor optical amplifiers, the laser sources and semiconductor optical amplifiers having, in pairs, an amplifying medium of the same composition, and a plurality of waveguides respectively disposed between laser sources and semiconductor optical amplifiers having amplifying mediums of different compositions.

16. The integrated photonic transmission circuit of claim 15, further comprising a wavelength multiplexer arranged downstream of the plurality of semiconductor optical amplifiers and optically connected to the semiconductor optical amplifiers to produce multispectral light radiation.

17. The integrated photonic transmission circuit of claim 1, further comprising at least one additional optical device arranged between the laser source and the semiconductor optical amplifier.

18. The integrated photonic transmitter circuit of claim 17, wherein the additional optical device is a modulator or a switch.
